(19) United States
(12) Patent Application Publication
(10) Pub. No.: US 2014/0354332 A1
(43) Pub. Date: Dec. 4, 2014

(54) SIGNAL TRANSMISSION DEVICE

(71) Applicants: HON HAI PRECISION INDUSTRY CO., LTD., Shenzhen (CN); HONG FU JIN I PRECISION INDUSTRY (ShenZhen) CO., LTD., Shenzhen (CN)

(72) Inventors: KANG WU, Shenzhen (CN); BO TIAN, Shenzhen (CN)

(73) Assignees: HON HAI PRECISION INDUSTRY CO., LTD., New Taipei (TW); HONG FU JIN I PRECISION INDUSTRY (ShenZhen) CO., LTD., Shenzhen (CN)

(21) Appl. No.: 14/134,234

(22) Filed: Dec. 19, 2013

(30) Foreign Application Priority Data
May 31, 2013 (CN) 2013102104871

(51) Int. Cl. H03K 3/01

(52) U.S. Cl. CPC H03K 3/01
USPC 327/108

(57) ABSTRACT

A signal transmission device includes a driver chip and a receiver. The driver chip is connected to a signal source to receive a first signal. The driver chip compensates the first signal into a second signal according to a preset coefficient. The driver chip outputs the second signal to the receiver.

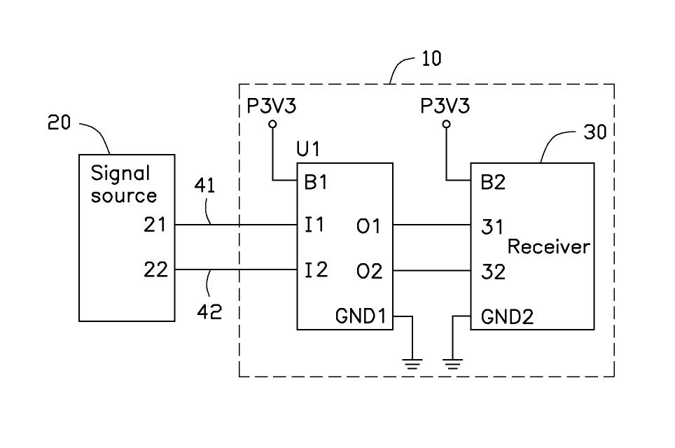

### BACKGROUND

1. Technical Field

The present disclosure relates to a signal transmission device.

2. Description of Related Art

Many kinds of connectors are used in a server. A signal line connecting two connectors can be too long to transmit a signal without signal attenuation.

Therefore, there is room for improvement in the art.

### BRIEF DESCRIPTION OF THE DRAWING

Many aspects of the present disclosure can be better understood with reference to the following drawing. The components in the drawing are not necessarily drawn to scale, the emphasis instead being placed upon clearly illustrating the principles of the present disclosure. Moreover, in the drawing, like reference numerals designate corresponding parts throughout the several views.

The FIGURE is a circuit diagram of an embodiment of a signal transmission device of the present disclosure.

### DETAILED DESCRIPTION

The FIGURE shows an embodiment of a signal transmission device 10 of the present disclosure.

The signal transmission device 10 comprises a driver chip U1 and a receiver 30. A signal source 20 outputs signals to the receiver 30 through the driver chip U1.

A first output pin 21 of the signal source 20 is connected to a first input pin I1 of the driver chip U1 through a signal line 41. A second output pin 22 of the signal source 20 is connected to a second input pin I2 of the driver chip U1 through a signal line 42. A first output pin O1 of the driver chip U1 is connected to a first input pin 31 of the receiver 30. A second output pin O2 of the driver chip U1 is connected to a second input pin 32 of the receiver 32. A voltage pin B1 of the driver chip U1 is connected to a power source P3V3. A ground pin GND1 of the driver chip U1 is grounded. A voltage pin B2 of the receiver 30 is connected to the power source P3V3. A ground pin GND2 of the receiver 30 is grounded.

The signal source 20 outputs a first signal to the driver chip U1. Signal attenuation of the first signal is generated in the transmission from the signal source 20 to the driver chip U1. When the first signal is transmitted to the driver chip U1, the driver chip U1 compensates the first signal according to a preset coefficient A1. The compensated first signal is a second signal. A signal intensity of the second signal is substantially the same as the original signal intensity of the first signal. The driver chip U1 outputs the second signal to the receiver 30.

In the embodiment, the signal transmission device 10 is a serial advanced technology attachment (SATA) connector. The driver chip U1 and the receiver 30 are located in the SATA connector. In another embodiment, the signal transmission device 10 can be a serial attached small computer systems interface (SAS) connector.

While the disclosure has been described by way of example and in terms of preferred embodiment, it is to be understood that the disclosure is not limited thereto. To the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A signal transmission device, comprising a driver chip and a receiver, wherein the driver chip is connected to a signal source to receive a first signal, the driver chip compensates the first signal into a second signal according to a preset coefficient, the driver chip outputs the second signal to the receiver.

2. The signal transmission device of claim 1, wherein the driver chip comprises a first input pin connected to a first output pin of the signal source, a second input pin connected to a second output pin of the signal source, a first output pin connected to a first input pin of the receiver, a second output pin connected to a second input pin of the receiver, a voltage pin connected to a power source, and a ground pin to ground, and the receiver comprises a voltage pin connected to the power source, and a ground pin to ground.

3. The signal transmission device of claim 1, wherein the signal transmission device is a serial advanced technology attachment (SATA) connector, the driver chip and the receiver are located in the SATA connector.

4. The signal transmission device of claim 1, wherein the signal transmission device is a serial attached small computer systems interface (SAS) connector, and the driver chip and the receiver are located in the SAS connector.

5. The signal transmission device of claim 1, wherein a signal intensity of the second signal is substantially the same as an original signal intensity of the first signal.
